(19) United States
(12) Patent Application Publication
(10) Pub. No.: US 2022/0123136 A1
(43) Pub. Date: Apr. 21, 2022

(54) GaN HIGH ELECTRON MOBILITY TRANSISTOR

(71) Applicant: NATIONAL SUN YAT-SEN UNIVERSITY, Kaohsiung (TW)

(72) Inventors: Ting-Chang Chang, Kaohsiung (TW); Hong-Chih Chen, Kaohsiung (TW); Hao-Xuan Zheng, Kaohsiung (TW); Yu-Shan Lin, Kaohsiung (TW); Fu-Yuan Jin, Kaohsiung (TW); Fong-Min Ciou, Kaohsiung (TW); Yun-Hsuan Lin, Kaohsiung (TW); Mao-Chou Tai, Kaohsiung (TW); Wen-Chung Chen, Kaohsiung (TW)

(21) Appl. No.: 17/200,943

(22) Filed: Mar. 15, 2021

(30) Foreign Application Priority Data
Oct. 15, 2020 (TW) 109135717

(51) Int. Cl. H01L 29/778; H01L 29/20

(52) U.S. Cl. CPC H01L 29/7786; H01L 29/2003

(57) ABSTRACT

A GaN high electron mobility transistor is disclosed. The GaN high electron mobility transistor includes a substrate, a buffer layer located on the substrate, a barrier layer laminated on the buffer layer, a channel layer laminated on the barrier layer, a supply layer laminated on the channel layer. The barrier layer has either a p-type semiconductor or a wide band gap material. A gate electrode is located on the supply layer. A source electrode and a drain electrode are electrically connected to the channel layer and the supply layer.

### CROSS REFERENCE TO RELATED APPLICATION

The application claims the benefit of Taiwan application serial No. 109135717, filed on Oct. 15, 2020, and the entire contents of which are incorporated herein by reference.

### BACKGROUND OF THE INVENTION

### 1. Field of the Invention

The present invention generally relates to an electronic component and, more particularly, to a gallium nitride (GaN) high electron mobility transistor with easy manufacturing process, simple operation and capable of reducing the kink effect.

### 2. Description of the Related Art

In recent years, industries such as electric vehicles and 5G communications develop rapidly and increase the performance specification and demands for electronic components. High-power, low-consumption and high-frequency electronic components have market advantages. Among them, gallium nitride has high breakdown voltage, high electron saturation drift rate, low resistivity, good chemical corrosion resistance and good thermal stability. Thus, it is an ideal semiconductor material. However, high electron mobility transistor with gallium nitride as the main material is affected by the kink effect. During the operation, a large number of electrons enter the buffer layer from the channel layer, which results in decreasing of output current and signal amplification and limits the performance and the reliability of the gallium nitride high electron mobility transistor.

Under high voltage operation, the above-mentioned conventional gallium nitride high electron mobility transistors have electrons accumulated in the buffer layer and cause adverse effect. To suppress the accumulation of electrons, it is required to modify the transistor structure through complicated manufacturing processes. For example, forming a hole extraction electrode near the source electrode, fabricating a side spacing of the vertical interface, or generating holes through illumination to recombine elections, etc. Those complicated manufacturing processes result in problems such as requiring additional photomask during the manufacturing process, increasing component production costs, and increasing power consumption during operation.

In light of the above problems, it is necessary to improve the conventional gallium nitride high electron mobility transistor.

### SUMMARY OF THE INVENTION

It is therefore an objective of the present invention to provide a GaN high electron mobility transistor which can suppress the kink effect and improve the performance of the transistor.

It is another objective of the present invention to provide a GaN high electron mobility transistor which can disperse the electric field intensity and increase the breakdown voltage of the transistor.

It is yet another objective of the present invention to provide a GaN high electron mobility transistor which can reduce the technical difficulty and cost of production.

As used herein, the term “a”, “an”, or “one” for describing the number of the elements and members of the present invention is used for convenience, provides the general meaning of the scope of the present invention, and should be interpreted to include one or at least one. Furthermore, unless explicitly indicated otherwise, the concept of a single component also includes the case of plural components.

A GaN high electron mobility transistor according to an embodiment includes a substrate, a buffer layer located on the substrate, a barrier layer laminated on the buffer layer, a channel layer laminated on the barrier layer, a supply layer laminated on the channel layer. The barrier layer has either a p-type semiconductor or a wide band gap material. A gate electrode is located on the supply layer. A source electrode and a drain electrode are electrically connected to the channel layer and the supply layer.

Accordingly, the GaN high electron mobility transistor according to the embodiment further utilizes a barrier layer additionally formed during the manufacturing process to prevent a large number of electrons from entering the buffer layer, which can suppress the kink effect and reduce the manufacturing cost. Further, in case the barrier layer is a p-type semiconductor, it can disperse the electric field intensity and increase the transistor breakdown voltage, ensuring the effects of improving the performance and increasing the reliability.

In an example, a material of the buffer layer is gallium nitride doped with carbon or gallium nitride doped with iron. Thus, the buffer layer can reduce the adverse effect of the hetero structure between the substrate and the transistor during the epitaxial process, ensuring the effects of improving the crystal quality and electronic characteristics of the transistor.

In an example, a material of the barrier layer is a p-type gallium nitride, p-type aluminum gallium nitride, p-type aluminum nitride, aluminum nitride, or aluminum gallium nitride. Thus, the barrier layer can recombine electrons with holes or block electrons with an electron energy barrier, ensuring the effect of suppressing the kink effect.

In an example, a material of the channel layer is gallium nitride, and a material of the supply layer is aluminum gallium nitride. Thus, the buffer layer can reduce the adverse effect of the heterostructure between the substrate and the channel layer on the epitaxial process, and the barrier layer can prevent a large number of electrons from entering the buffer layer, ensuring the effect of enhancing the reliability of the transistor.

In an example, the GaN high electron mobility transistor further includes a passivation layer laminated on the supply layer, the gate electrode, the source electrode, and the drain electrode. Thus, a two-dimensional electron gas can be formed at the heterostructure interface between the supply layer, and the channel layer is to provide as a channel for electrons to move quickly, ensuring the effect of improving the high frequency operation of the transistor.

In an example, the GaN high electron mobility transistor further includes a passivation layer laminated on the supply layer, the gate electrode, the source electrode, and the drain electrode. Thus, the passivation layer can protect the electrical characteristics of the underlying layers and electrodes from being affected by the environment, ensuring the effect of improving the reliability of the transistor.

In an example, a material of the passivation layer is silicon nitride, silicon dioxide, or aluminum oxide. Thus, the passivation layer has the characteristics such as thermal shock resistance and electrical insulation, ensuring the effects of protecting the transistor structure and preventing electrodes from short circuit.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 is a lamination cross-sectional diagram according to a preferred embodiment of the present invention.

FIG. 2 is a lamination comparison diagram between a preferred embodiment of the present invention and a prior art.

FIG. 3 is an electron density distribution diagram along lines A-A′ and B-B′ shown in FIG. 2.

In the various figures of the drawings, the same numerals designate the same or similar parts. Furthermore, when the terms “left”, “right”, “up (top)”, “low (bottom)”, and similar terms are used herein, it should be understood that these terms have reference only to the structure shown in the drawings as it would appear to a person viewing the drawings and are utilized only to facilitate describing the invention, rather than restricting the invention.

### DETAILED DESCRIPTION OF THE INVENTION

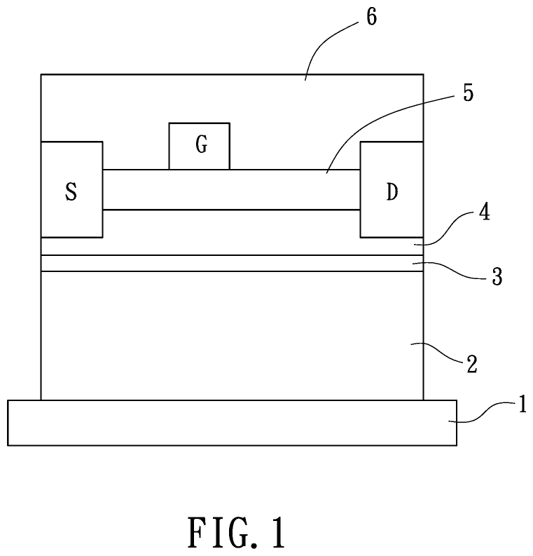

Referring to FIG. 1, the GaN high electron mobility transistor according to a preferred embodiment of the present invention includes a substrate 1, a buffer layer 2, a barrier layer 3, a channel layer 4, and a supply layer 5. The buffer layer 2 is located on the substrate 1. The barrier layer 3 is laminated on the buffer layer 2. The channel layer 4 and the supply layer 5 are laminated sequentially on the barrier layer 3.

The substrate 1 carries transistors. The loss of electrons can be decreased, and harmful electrical effects can be prevented, by having transistor materials such as metal, insulators and semiconductors formed on the substrate 1. The material of the substrate 1 is preferably silicon.

The buffer layer 2 is formed on the substrate 1 before epitaxial growth, and then each epitaxial layer of the transistor is formed on the buffer layer 2. The buffer layer 2 can reduce the adverse effect of the heterostructure between the substrate 1 and the transistor on the epitaxial process, so as to improve the crystal quality and electronic characteristics of the transistor. In this embodiment, the material of the buffer layer 2 is gallium nitride doped with carbon (GaN:C) or gallium nitride doped with iron (GaN:Fe).

The barrier layer 3 prevents the electrons from injecting into the buffer layer 2. The barrier layer 3 may be a p-type semiconductor, so as to generate additional holes to capture the electrons by recombination defects. Thus, the large number of electrons can be prevented from entering the buffer layer 2. Utilizing the material of p-type semiconductor may also disperse the electric field intensity and increase the breakdown voltage of the transistor. Further, the barrier layer 3 may also have a wide band gap material. By forming a higher electronic energy barrier on the barrier layer 3, the electrons in the barrier layer 3 may be blocked. In this embodiment, the material of the barrier layer 3 may be p-type gallium nitride (p-GaN), p-type aluminum gallium nitride (p-AlGaN), p-type aluminum nitride (p-A1N), aluminum nitride (AlN), or aluminum gallium nitride (AlGaN), etc.

In addition, in the process of manufacturing the GaN high electron mobility transistor, the buffer layer 2 may be formed first, followed by another epitaxial layer of the barrier layer 3. Thus, it does not require additional photomask or complicated manufacturing process to form a special-shaped suppression structure, achieving the effects of reducing the cost for production and increasing performance of the transistor.

The channel layer 4 and the supply layer 5 have materials with energy gaps different from each other. A two-dimensional electron gas (2DEG) is formed at the heterostructure interface between the channel layer 4 and the supply layer 5. Therefore, a channel for rapid electron migration is provided to render the transistor good characteristics of high frequency operation. In this embodiment, the material of the channel layer 4 may be gallium nitride, and the material of the supply layer 5 may be gallium aluminum nitride.

The p-type GaN high electron mobility transistor further has a gate electrode G, a source electrode S, and a drain electrode D. The gate electrode G is located on the supply layer 5. The source electrode S and the drain electrode D are electrically connected to the channel layer 4 and the supply layer 5. Therefore, the electrons between the source electrode S and the drain electrode D can efficiently migrate between the channel layer 4 and the supply layer 5. Furthermore, the output current of the drain electrode D can be adjusted by the electric field provided between the gate electrode G and the substrate 1.

The GaN high electron mobility transistor may further include a passivation layer 6, which is laminated on the supply layer 5, the gate electrode G, the source electrode S, and the drain electrode D. As such, the passivation layer 6 can protect the electrical characteristics of the underlying layers and electrodes from being affected by the environment, ensuring the effect of improving the reliability of the transistor. In this embodiment, the material of the passivation layer 6 may be silicon nitride (SiN), silicon dioxide (SiO₂), or aluminum oxide (Al₂O₃), etc., which has the characteristics such as thermal shock resistance and electrical insulation.

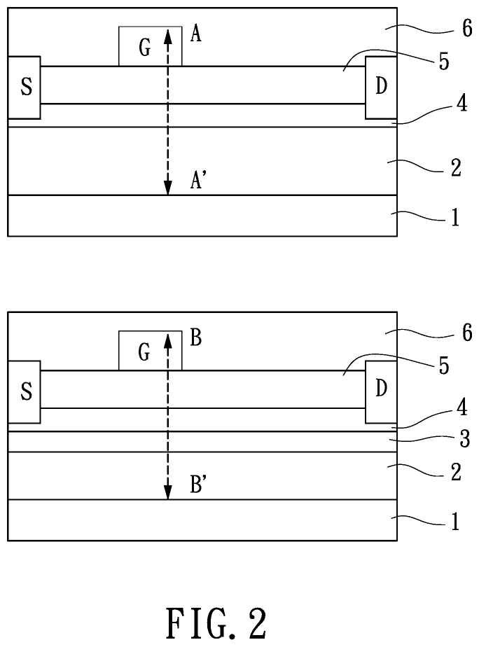

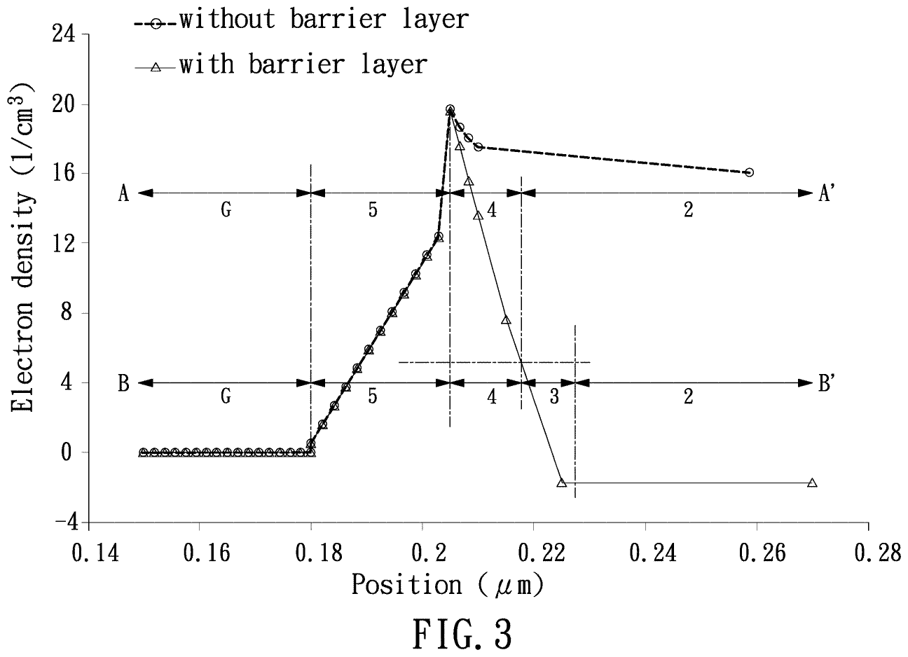

Referring to FIGS. 2 and 3, compared with the conventional lamination structure, the GaN high electron mobility transistor according to a preferred embodiment of the invention further includes the barrier layer 3 formed between the buffer layer 2 and the channel layer 4. Also, as shown in FIG. 3, an electron density distribution diagram of the foregoing two lamination structures during operation corresponds to each position along lines A-A′ and B-B′ shown in FIG. 2. The electron density varies from the gate electrode G, the supply layer 5, the channel layer 4 to the buffer layer 2 in order. Among them, the electron density has a maximum at the junction between the channel layer 4 and the supply layer 5, provided as a channel for electrons to move; the electron density decreases slowly as the electrons directly entering the buffer layer 2 from the channel layer 4, and the electron density still remains at a high value in the buffer layer 2; the electron density drops sharply from the channel layer 4 through the barrier layer 3 to the buffer layer 2, and the electron density in the buffer layer 2 decreases to zero. Therefore, by forming the barrier layer 3 between the buffer layer 2 and the channel layer 4, the electrons are effectively prevented from entering the buffer layer 2, which can achieve the effect of suppressing the kink effect.

Although the invention has been described in detail with reference to its presently preferable embodiments, it will be understood by one of ordinary skill in the art that various modifications can be made without departing from the spirit and the scope of the invention, as set forth in the appended claims.

What is claimed is:

1. A GaN high electron mobility transistor comprising:
a substrate;
a buffer layer located on the substrate;
a barrier layer laminated on the buffer layer and having either a p-type semiconductor or a wide band gap material;
a channel layer laminated on the barrier layer; and
a supply layer laminated on the channel layer, wherein a gate electrode is located on the supply layer, and a source electrode and a drain electrode are electrically connected to the channel layer and the supply layer.

2. The GaN high electron mobility transistor as claimed in claim 1, wherein a material of the buffer layer is gallium nitride doped with carbon or gallium nitride doped with iron.

3. The GaN high electron mobility transistor as claimed in claim 2, further comprising a passivation layer laminated on the supply layer, the gate electrode, the source electrode, and the drain electrode.

4. The GaN high electron mobility transistor as claimed in claim 3, wherein a material of the passivation layer is silicon nitride, silicon dioxide, or aluminum oxide.

5. The GaN high electron mobility transistor as claimed in claim 1, wherein a material of the barrier layer is a p-type gallium nitride, p-type aluminum gallium nitride, p-type aluminum nitride, aluminum nitride, or aluminum gallium nitride.

6. The GaN high electron mobility transistor as claimed in claim 5, further comprising a passivation layer laminated on the supply layer, the gate electrode, the source electrode, and the drain electrode.

7. The GaN high electron mobility transistor as claimed in claim 6, wherein a material of the passivation layer is silicon nitride, silicon dioxide, or aluminum oxide.

8. The GaN high electron mobility transistor as claimed in claim 1, wherein a material of the channel layer is gallium nitride, and a material of the supply layer is aluminum gallium nitride.

9. The GaN high electron mobility transistor as claimed in claim 8, further comprising a passivation layer laminated on the supply layer, the gate electrode, the source electrode, and the drain electrode.

10. The GaN high electron mobility transistor as claimed in claim 9, wherein a material of the passivation layer is silicon nitride, silicon dioxide, or aluminum oxide.

11. The GaN high electron mobility transistor as claimed in claim 1, further comprising a passivation layer laminated on the supply layer, the gate electrode, the source electrode, and the drain electrode.

12. The GaN high electron mobility transistor as claimed in claim 11, wherein a material of the passivation layer is silicon nitride, silicon dioxide, or aluminum oxide.
